(19) United States
(12) Patent Application Publication
(10) Pub. No.: US 2025/0331432 A1
(43) Pub. Date: Oct. 23, 2025

(54) SEMICONDUCTOR DEVICE INCLUDING MEMORY STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Yong-Sheng HUANG, Hsinchu (TW); Fu-Ting SUNG, Hsinchu (TW); Hsia-Wei CHEN, Hsinchu (TW); Yu-Jui TSENG, Hsinchu (TW); Tzu-Cheng CHAO, Hsinchu (TW); Yu-Wen LIAO, Hsinchu (TW); Wen-Ting CHU, Hsinchu (TW)

(73) Assignee: TAIWAN SEMICONDUCTOR MANUFACTURING COMPANY, LTD., Hsinchu (TW)

(21) Appl. No.: 18/640,921

(22) Filed: Apr. 19, 2024

(51) Int. Cl. H10N 70/00; H10B 63/00; H10N 70/20

(52) U.S. Cl. CPC H10N 70/063; H10B 63/00; H10N 70/24; H10N 70/841

(57) ABSTRACT

A method for manufacturing a semiconductor device includes: forming a hard mask layer including a first hard mask material; forming a memory structure on the hard mask layer; forming a lower hard mask on the memory structure, the lower hard mask including a second hard mask material the same as the first hard mask material; forming an upper hard mask on the lower hard mask, the upper hard mask including a third hard mask material different from the second hard mask material; forming an interlayer dielectric layer on the hard mask layer; forming a first via opening and a second via opening, the first via opening penetrating the interlayer dielectric layer, the upper hard mask, and the lower hard mask to expose the memory structure; and forming a first contact via and a second contact via, the first contact via being connected to the memory structure.

### BACKGROUND

With the increasingly scaling down of the size of the semiconductor memory structures, a resistive random-access memory (RRAM) structure becomes one of the most notable candidates to replace a flash memory structure (for example, but not limited to, an NAND flash memory structure). One of the advantages of the RRAM structure over the flash memory structure is that the size of the RRAM structure can be scaled down to be less than 10 nm.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor device in accordance with some embodiments.

FIGS. 2 to 11 are schematic views showing some intermediate stages of the method depicted in FIG. 1.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “top,” “bottom,” “below,” “upward,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a method for manufacturing a semiconductor device including an RRAM structure, silicon oxynitride is usually used as a hard mask material in formation of the RRAM structure due to a high etching selectivity thereof, so that the RRAM structure can be defined. However, the hard mask material (i.e., silicon oxynitride) used to define the RRAM structure is usually different from a hard mask material (for example, silicon carbide) used in a logic structure region. As the size of the RRAM structure is being increasingly scaled down in the advanced technology nodes, a process window for forming a via opening to expose the RRAM structure, which is performed by patterning the hard mask material of silicon oxynitride, is strictly limited. That is, the via opening to expose the RRAM structure and a via opening in the logic structure region are formed at the same time by a patterning process so as to remove a portion of silicon oxynitride disposed above the RRAM structure and a portion of silicon carbide disposed above a corresponding one of metal lines in the logic structure region. If the thickness of silicon oxynitride is not controlled precisely, the portion of silicon oxynitride disposed above the RRAM structure may not be removed completely when the portion of silicon carbide in the logic structure region is removed completely. Therefore, a contact via formed by filling a conductive material in the via opening above the RRAM structure may be isolated from the RRAM structure by residues of silicon oxynitride, causing failure in the performance of a semiconductor device including the RRAM structure. The present disclosure is directed to a method for manufacturing a semiconductor device including the RRAM structure, in which a bi-layered hard mask is provided during the formation of the RRAM structure to avoid isolation of a contact via formed above the RRAM structure from the RRAM structure due to the presence of residues of a hard mask material.

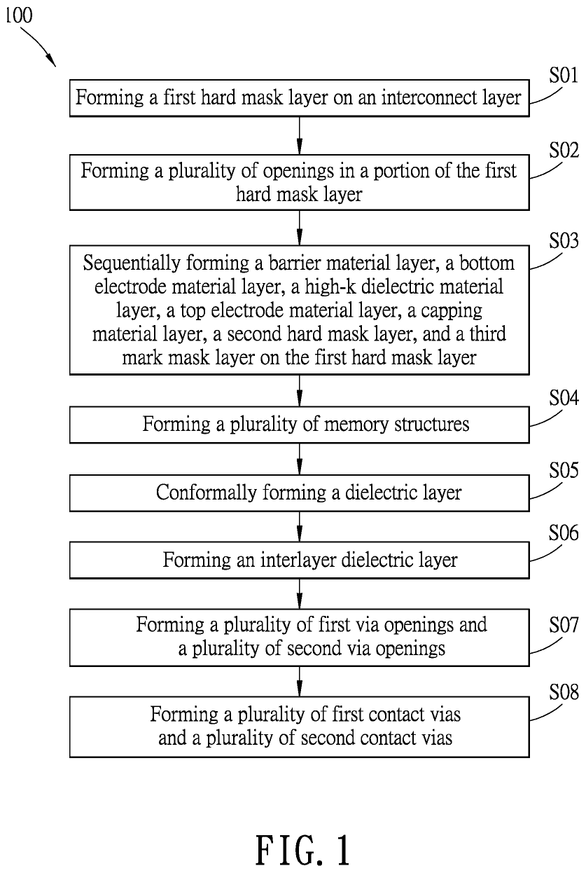

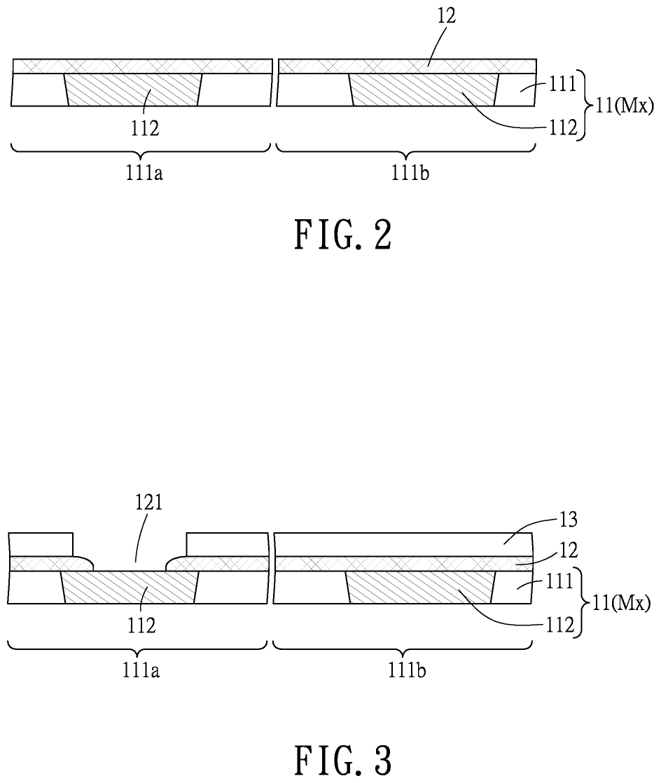

FIG. 1 is a flow diagram illustrating an exemplary method 100 for manufacturing an exemplary semiconductor device 200 as shown in FIG. 11 in accordance with some embodiments. FIGS. 2 to 10 are schematic views of some intermediate stages of the method 100 as depicted in FIG. 1 in accordance with some embodiments. Some portions are omitted in FIGS. 2 to 11 for the sake of brevity. Additional steps can be provided before, after or during the method 100, and some of the steps described herein may be replaced by other steps or be eliminated.

Referring to FIG. 1 and the example illustrated in FIG. 2, the method 100 begins at step S01, where a first hard mask layer 12 is formed on an interconnect layer 11 disposed on a semiconductor substrate (not shown).

In some embodiments, the semiconductor substrate may include, for example, but not limited to, an elemental semiconductor or a compound semiconductor. The elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. The compound semiconductor includes two or more elements, and examples thereof may include, but not limited to, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate may include a multilayer compound semiconductor substrate. In some embodiments, the semiconductor substrate may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. Other suitable materials are within the contemplated scope of the present disclosure. The SOI substrate may be doped with a P-type dopant, for example, but not limited to, boron (Br), aluminum (Al), or gallium (Ga). Other suitable P-type dopant materials are within the contemplated scope of the present disclosure. Alternatively, the SOI substrate may be doped with an N-type dopant, for example, but not limited to, nitrogen (N), phosphorus (P), or arsenic (As). Other suitable N-type dopant materials are within the contemplated scope of the present disclosure.

In some embodiments, the interconnect layer 11 is configured as a metal line layer (Mx), which includes a dielectric layer 111 (for example, an inter-metal dielectric layer), and a plurality of metal lines 112 (i.e., conductive interconnects) disposed in the dielectric layer 111 and spaced apart from each other. In some embodiments, the interconnect layer 11 is formed by a single damascene process depicted as follows.

The dielectric layer 111 is formed on another interconnect layer (not shown) that is disposed on the semiconductor substrate. In some embodiments, the another interconnect layer includes a plurality of contact vias (not shown) that are disposed in another dielectric layer (not shown) below the interconnect layer 11 and that are spaced apart from each other. In some embodiments, the dielectric layer 111 may include, for example, but not limited to, silicon oxide, silicon nitride, silicon carbide, silicon oxycarbide, silicon oxynitride, silicon carbonitride, silicon oxycarbonitride, undoped silicate glass (USG), phosphosilicate glass (PSG), borosilicate glass (BSG), boron-doped phosphosilicate glass (BPSG), fluorine-doped silicate glass (FSG), an extreme low k (ELK) dielectric material, or combinations thereof. Other suitable dielectric materials for the dielectric layer 111 are within the contemplated scope of the present disclosure. In some embodiments, the dielectric layer 111 may be formed by a suitable deposition process as is known in the art of semiconductor fabrication, for example, but not limited to, chemical vapor deposition (CVD), physical vapor deposition (PVD), atomic layer deposition (ALD), or other suitable deposition processes. In some embodiments, the dielectric layer 111 may include a memory structure region 111a and a logic structure region 111b.

A plurality of the metal lines 112 are then formed in the dielectric layer 111 by patterning the dielectric layer 111 to form a plurality of trenches (not shown) spaced apart from each other, followed by depositing a metallic material on the dielectric layer 111 to fill the trenches, and then removing excess of the metallic material on the dielectric layer 111.

In some embodiments, the dielectric layer 111 may be patterned by photolithography, which includes an etching processes, so as to form the trenches. The photolithography may include, for example, but not limited to, coating a photoresist on the dielectric layer 111, soft-baking the photoresist, exposing the photoresist through a photomask, post-exposure baking the photoresist, and developing the photoresist, followed by hard-baking the photoresist so as to form a patterned photoresist on the dielectric layer 111. In the etching process, the dielectric layer 111 may be etched by a suitable etching process as is known in the art of semiconductor fabrication, for example, but not limited to, dry etching, wet etching, a combination thereof, or other suitable etching processes, so as to form the trenches.

In some embodiments, the metallic material may be deposited by a suitable deposition process as is known in the art of semiconductor fabrication, for example, but not limited to, CVD, PVD, ALD, electroless plating, electroplating, or other suitable deposition processes.

In some embodiments, removal of excess of the metallic material on the dielectric layer 111 may be performed by a suitable planarization process as is known in the art of semiconductor fabrication, for example, but not limited to, a chemical mechanical polishing (CMP) process, an etching back process, or other suitable planarization processes. The metallic material for forming the metal lines 112 may include, for example, but not limited to, copper, aluminum, tungsten, or combinations thereof. Other suitable materials for the metal lines 112 are within the contemplated scope of the present disclosure.

In some embodiments, one or more of the metal lines 112 are respectively in contact with corresponding one(s) of the contact vias of the another interconnect layer disposed below the interconnect layer 11.

The first hard mask layer 12 is formed on the dielectric layer 111 and the metal lines 112 by a suitable deposition process as is known in the art of semiconductor fabrication, for example, but not limited to, PVD, CVD, plasma-enhanced CVD (PECVD), ALD, spin-on coating, or other suitable deposition processes. In some embodiments, in this step, after formation of the first hard mask layer 12, a top surface of the first hard mask layer 12 may be planarized by a suitable planarization process (e.g., the CMP process or other suitable planarization processes). The first hard mask layer 12 is made of a first hard mask material. In some embodiments, the first hard mask material may include, for example, but not limited to, silicon nitride, silicon oxide, silicon carbide, silicon oxynitride, silicon oxycarbide, silicon carbon nitride, or combinations thereof. Other suitable materials for the first hard mask layer 12 are within the contemplated scope of the present disclosure. In some embodiments, the first hard mask layer 12 includes silicon carbide.

Referring to FIG. 1 and the example illustrated in FIG. 3, the method 100 proceeds to step S02, where a plurality of openings 121 are formed in a portion of the first hard mask layer 12 in the memory structure region 111a, so as to expose the metal lines 112 in the memory structure region 111a. One of the openings 121 is shown in FIG. 3. Step 02 may be performed by patterning the first hard mask layer 12 using a patterned photoresist layer 13 disposed on the first hard mask layer 12 so as to form the openings 121. The patterning process may be a photolithography process of forming the trenches of the dielectric layer 111 as described above in step S01 with reference to FIG. 2, and details thereof are omitted for the sake of brevity. After this step, the patterned photoresist layer 13 is removed by, for example, but not limited to, an ashing process.

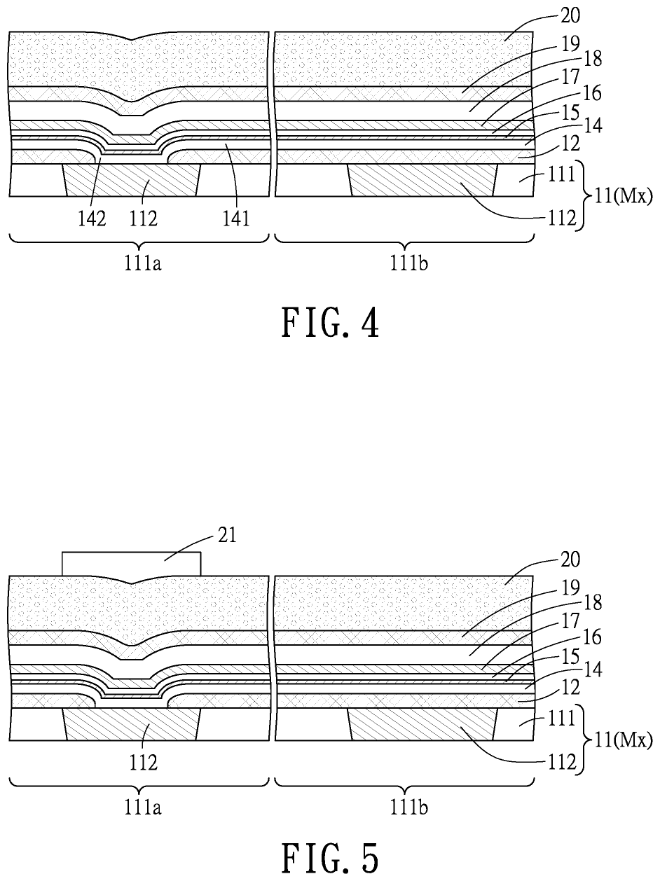

Referring to FIG. 1 and the example illustrated in FIG. 4, the method 100 proceeds to step S03, where a barrier material layer 14, a bottom electrode material layer 15, a high-k dielectric material layer 16, a top electrode material layer 17, a capping material layer 18, a second hard mask layer 19, and a third hard mask layer 20 are formed sequentially on the first hard mask layer 12. That is, the barrier material layer 14 is formed on the first hard mask layer 12 opposite to the interconnect layer 11, the bottom electrode material layer 15 is formed on the barrier material layer 14 opposite to the first hard mask layer 12, the high-k dielectric material layer 16 is formed on the bottom electrode material layer 15 opposite to the barrier material layer 14, the top electrode material layer 17 is formed on the high-k dielectric material layer 16 opposite to the bottom electrode material layer 15, the capping material layer 18 is formed on the top electrode material layer 17 opposite to the high-k dielectric material layer 16, the second hard mask layer 19 is formed on the capping material layer 18 opposite to the top electrode material layer 17, and the third hard mask layer 20 is formed on the second hard mask layer 12 opposite to the capping material layer 18.

In some embodiments, the barrier material layer 14 is formed on a top surface of the first hard mask layer 12 and fills the openings 121 (see FIG. 2) by a suitable deposition process as is known in the art of semiconductor fabrication, for example, but not limited to, CVD, PVD, ALD, or other suitable deposition processes. In some embodiments, the barrier material layer 14 includes, for example, but not limited to, platinum, aluminum, copper, gold, titanium, tantalum, tungsten, alloys thereof, tantalum nitride, titanium nitride, tungsten nitride, or combinations thereof. Other suitable materials for the barrier material layer 14 are within the contemplated scope of the present disclosure. The barrier material layer 14 is in direct contact with the metal lines 11 exposed from the openings 121. The barrier material layer 14 includes a layer portion 141 disposed on the first hard mask layer 12, and a plurality of insert portions 142 that are formed integrally with the layer portion 141 and that are respectively inserted into the openings 121.

In some embodiments, the bottom electrode material layer 15 is formed on the barrier material layer 14 by a suitable deposition process as is known in the art of semiconductor fabrication, for example, but not limited to, CVD, PVD, ALD, or other suitable deposition processes. In some embodiments, the bottom electrode material layer 15 includes, for example, but not limited to, platinum, aluminum, copper, gold, titanium, tantalum, tungsten, alloys thereof, titanium nitride, tantalum nitride, tungsten nitride, or combinations thereof. Other suitable materials for the bottom electrode material layer 15 are within the contemplated scope of the present disclosure. The bottom electrode material layer 15 is electrically connected to the metal lines 112 through the barrier material layer 14. In some embodiments, the bottom electrode material layer 15 and the barrier material layer 14 may include different materials.

In some embodiments, the high-k dielectric material layer 16 is formed on the bottom electrode material layer 15 by a suitable deposition process as is known in the art of semiconductor fabrication, for example, for example, but not limited to, CVD, PVD, ALD, plasma-enhanced ALD, molecular beam epitaxy (MBE), or other suitable deposition processes. In some embodiments, the high-k dielectric material layer 16 may include binary oxides, ternary oxides, quaternary oxides, nitrides, or combinations thereof. The binary oxides may include, for example, but not limited to, hafnium oxide or other suitable materials. The ternary oxides may include, for example, but not limited to, hafnium silicate, hafnium zirconate, barium titanate, lead titanate, strontium titanate, calcium manganite, bismuth ferrite, doped hafnium oxide (the dopants may include, for example, but not limited to, yttrium (Y), scandium (Sc), gallium (Ga), gadolinium (Gd), other suitable dopants, or combinations thereof), or combinations thereof. The quaternary oxides may include, for example, but not limited to, lead zirconate titanate, barium strontium titanate, strontium bismuth tantalate, or combinations thereof. The nitrides may include, for example, but not limited to, aluminum scandium nitride, aluminum gallium nitride, aluminum yttrium nitride, or combinations thereof. Other suitable high-k dielectric materials are within the contemplated scope of the present disclosure. In some embodiments, the high-k dielectric material layer 16 may be formed as a single layer structure or a multi-layered structure. In some embodiments, when the high-k dielectric material layer 16 is formed as the multi-layered structure, the high-k dielectric material layer 16 may include a plurality of films made of different materials.

The top electrode material layer 17 is formed on the high-k dielectric material layer 16 opposite to the bottom electrode material layer 15. The material and process for forming the top electrode material layer 17 may be the same as or similar to those for forming the bottom electrode material layer 15, and thus details thereof are omitted for the sake of brevity. In some embodiments, the top electrode material layer 17 may be formed as a single layer structure or a multi-layered structure. Similarly, the bottom electrode material layer 15 may be formed as a single layer structure or a multi-layered structure.

In some embodiments, the capping layer 18 is formed on the top electrode material layer 17 by a suitable deposition process as is known in the art of semiconductor fabrication, for example, but not limited to, CVD, PVD, ALD, or other suitable deposition processes. The capping layer 18 is a metal capping layer. In some embodiments, the capping layer 18 is a cobalt capping layer.

In some embodiments, the second hard mask layer 19 is formed on the capping layer 18 by a suitable deposition process as is known in the art of semiconductor fabrication, for example, but not limited to, PVD, CVD, PECVD, ALD, spin-on coating, or other suitable deposition processes. The second hard mask layer 19 is made of a second hard mask material. In some embodiments, the second hard mask material may include, for example, but not limited to, silicon nitride, silicon oxide, silicon carbide, silicon oxynitride, silicon oxycarbide, silicon carbon nitride, or combinations thereof. Other suitable materials for the second hard mask layer 19 are within the contemplated scope of the present disclosure. In the present disclosure, the second hard mask material for making the second hard mask layer 19 is the same as the first hard mask material for making the first hard mask layer 12, and the second hard mask layer 19 has a thickness which is equal to that of the first hard mask layer 12. In some embodiments, both of the first hard mask layer 12 and the second hard mask layer 19 include silicon carbide.

In some embodiments, the third hard mask layer 20 is formed on the second hard mask layer 19 by a suitable deposition process as is known in the art of semiconductor fabrication, for example, but not limited to, PVD, CVD, PECVD, ALD, spin-on coating, or other suitable deposition processes. The third hard mask layer 20 is made of a third hard mask material. In some embodiments, the third hard mask material may include, for example, but not limited to, silicon nitride, silicon oxide, tetraethyl orthosilicate (TEOS), silicon carbide, silicon oxynitride, silicon oxycarbide, silicon carbon nitride, or combinations thereof. Other suitable materials for the third hard mask layer 20 are within the contemplated scope of the present disclosure. In the present disclosure, the third hard mask material for making the third hard mask layer 20 is different from the first hard mask material for making the first hard mask layer 12 and the second hard mask material for making the second hard mask layer 19. In some embodiments, the third hard mask material for making the third hard mask layer 20 has a dielectric constant value (k-value) different from that of the second hard mask material for making the second hard mask layer 19. In some embodiments, the dielectric constant value of the third hard mask material is less than that of the second hard mask material. In some embodiments, the third hard mask layer 20 includes TEOS, silicon oxide, or a combination thereof. In some embodiments, the third hard mask layer 20 has a thickness which is greater than that of the second hard mask layer 19.

Referring to FIG. 1 and the examples illustrated in FIGS. 5 to 7, the method 100 proceeds to step S04, where a plurality of memory structures 22 are formed. Referring to the example illustrated in FIG. 5, a patterned photoresist layer 21 is formed on the structure shown in FIG. 4. The processes for forming the patterned photoresist layer 21 may be the same as or similar to those for forming the patterned photoresist described above in step S01 with reference to FIG. 2, and thus details thereof are omitted for the sake of brevity.

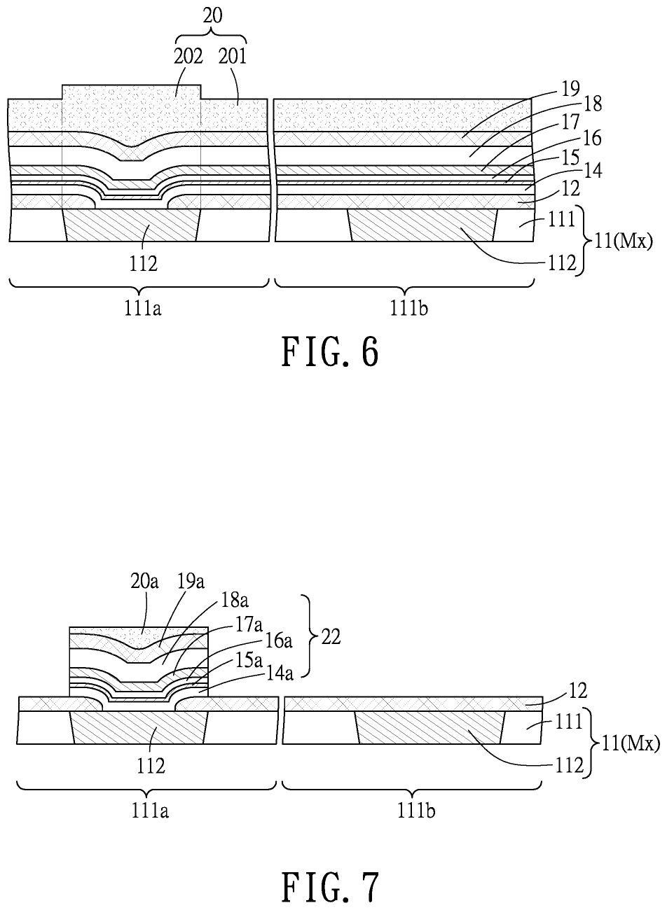

Referring to the examples illustrated in FIGS. 5 and 6, a dry etching process (for example, but not limited to, an anisotropic dry etching process) is performed through the patterned photoresist layer 21 to pattern the third hard mask layer 20 while gradually removing the patterned photoresist layer 21, so as to permit the third hard mask layer 20 to include a bottom portion 201 and a plurality of upper portions 202 protruding in an upward direction away from the interconnect layer 11. One of the upper portions 202 of the third hard mask layer 20 is shown in FIG. 6.

Referring to the examples illustrated in FIGS. 6 and 7, the dry etching process is performed continuously through a patterned hard mask formed by the upper portions 202 of the third hard mask layer 20 until the first hard mask layer 12 is exposed, so as to form a plurality of memory structures 22 (for example, the RRAM structures). One of the memory structures 22 is shown in FIG. 7. The first hard mask layer 12 serves as an etch stop layer for the dry etching process.

The memory structures 22 are respectively connected to the metal lines 112 in the memory structure region 111a of the interconnect layer 11. Each of the memory structures 22 includes a barrier 14a disposed on a corresponding one of the metal lines 112, a bottom electrode 15a disposed on the barrier 14a opposite to the corresponding one of the metal lines 112, a high-k dielectric element 16a disposed on the bottom electrode 15a opposite to the barrier 14a, a top electrode 17a disposed on the high-k dielectric element 16a opposite to the bottom electrode 15a, and a cap 18a disposed on the top electrode 17a opposite to the high-k dielectric element 16a. A lower hard mask 19a is formed on the cap 18a of each of the memory structures 22, and an upper hard mask 20a is formed on the lower hard mask 19a opposite to a corresponding one of the memory structures 22. The barrier 14a, the bottom electrode 15a, the high-k dielectric element 16a, the top electrode 17a, the cap 18a, the lower hard mask 19a, and the upper hard mask 20a are formed from the barrier material layer 14, the bottom electrode material layer 15, the high-k dielectric material layer 16, the top electrode material layer 17, the capping material layer 18, the second hard mask layer 19, and the third hard mask layer 20, respectively, by the dry etching process. The lower hard mask 19a, which is formed from the second hard mask layer 19 by the dry etching process, has a thickness which is equal to that of the first hard mask layer 12. In addition, the lower hard mask 19a includes a hard mask material (for example, but not limited to, silicon carbide) which is the same as that of the first hard mask layer 12. The upper hard mask 20a includes another hard mask material (for example, but not limited to, silicon oxide, TEOS, or a combination thereof) which is different from that (for example, but not limited to, silicon carbide) of the lower hard mask 19a.

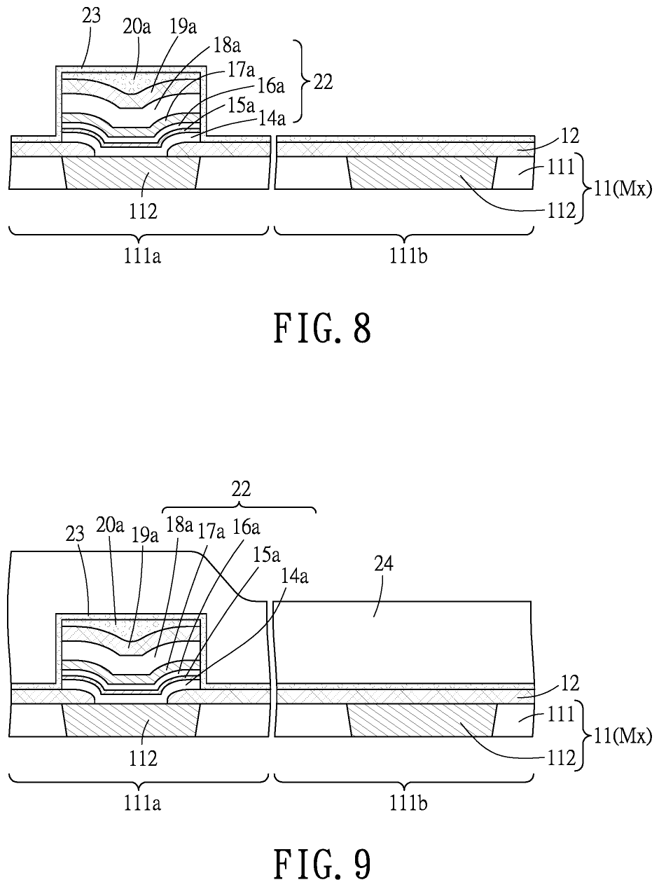

Referring to FIG. 1 and the example illustrated in FIG. 8, the method 100 proceeds to step S05, where a conformal dielectric layer 23 is conformally formed. The conformal dielectric layer 23 is conformally formed on the structure shown in FIG. 7 to cover the memory structures 22, the lower hard mask 19a, the upper hard mask 20a, and the first hard mask layer 12. In some embodiments, the conformal dielectric layer 23 include, for example, but not limited to, silicon nitride, silicon oxide, TEOS, silicon carbide, silicon oxynitride, silicon oxycarbide, silicon carbon nitride, or combinations thereof. Other suitable materials for the conformal dielectric layer 23 are within the contemplated scope of the present disclosure. In the present disclosure, both of the conformal dielectric layer 23 and the third hard mask layer 20 (i.e., the upper hard mask 20a) include the same material. In some embodiments, both of the conformal dielectric layer 23 and the third hard mask layer 20 (i.e., the upper hard mask 20a) include silicon oxide, TEOS, or a combination thereof. In some embodiments, the conformal dielectric layer 23 may be formed by a suitable conformal deposition process as is known in the art of semiconductor fabrication, for example, but not limited to, CVD, PVD, ALD, or other suitable deposition processes.

Referring to FIG. 1 and the example illustrated in FIG. 9, the method 100 proceeds to step S06, where an interlayer dielectric layer 24 is formed. The interlayer dielectric layer 24 is formed over the structure shown in FIG. 8. In some embodiments, the interlayer dielectric layer 24 is formed by a suitable deposition process as is known in the art of semiconductor fabrication, for example, but not limited to, PVD, CVD, PECVD, ALD, spin-on coating, or other suitable deposition processes. In some embodiments, the interlayer dielectric layer 24 may include, for example, but not limited to, silicon nitride, silicon oxide, silicon carbide, silicon oxynitride, silicon oxycarbide, silicon carbon nitride, an extreme low k (ELK) dielectric material, or combinations thereof. Other suitable materials for the interlayer dielectric layer 24 are within the contemplated scope of the present disclosure. In some embodiments, the interlayer dielectric layer 24 includes the ELK dielectric material.

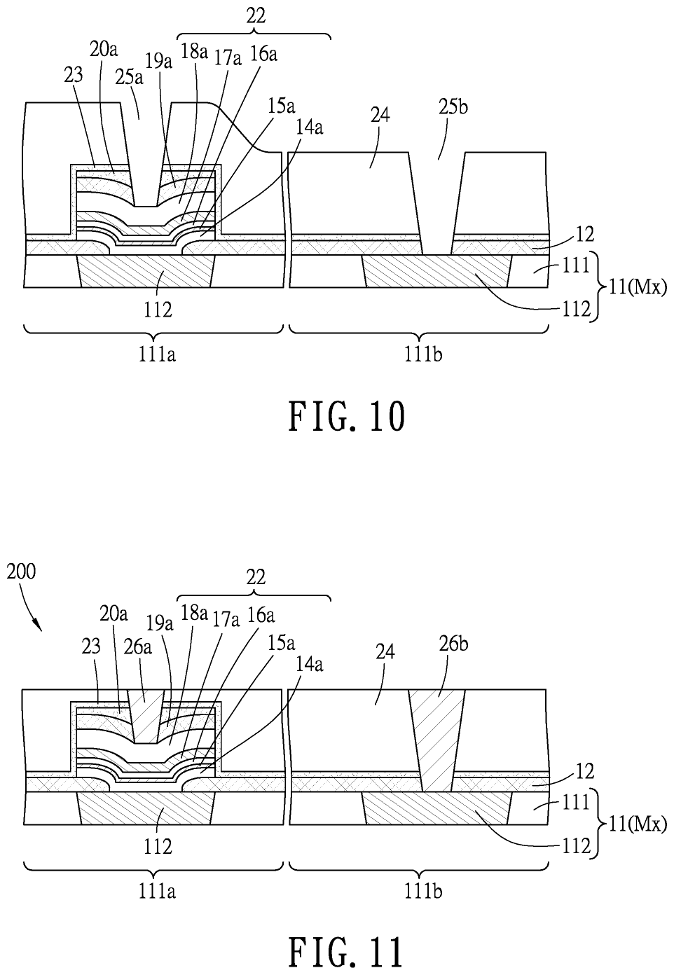

Referring to FIG. 1 and the example illustrated in FIG. 10, the method 100 proceeds to step S07, where a plurality of first via openings 25a and a plurality of second via openings 25b are formed. The interlayer dielectric layer 24, the conformal dielectric layer 23, the upper hard mask 20a, the lower hard mask 19a, and the first hard mask layer 12 are patterned by at least one etching process, so as to form a plurality of the first via openings 25a and a plurality of the second via openings 25b. In the at least one etching process, the interlayer dielectric layer 24, the conformal dielectric layer 23, and the upper hard mask 20a are etched using an etchant, and the lower hard mask 19a and the first hard mask layer 12 are then patterned using another etchant, which is different from the etchant for etching the interlayer dielectric layer 24, the conformal dielectric layer 23, and the upper hard mask 20a. When the interlayer dielectric layer 24, the conformal dielectric layer 23, and the upper hard mask 20a are etched using the etchant, each of the lower hard mask 19a and the first hard mask layer 12 serves as an etch stop layer.

As described above, the lower hard mask 19a is formed from the second hard mask layer 19 which includes a hard mask material the same as that of the first hard mask layer 12 and which has a thickness equal to that of the first hard mask layer 12, so that the lower hard mask 19a has an etching rate the same as that of the first hard mask layer 12 with respect to the another etchant and has a thickness equal to that of the first hard mask layer 12. Therefore, each of the first via openings 25a can penetrate the interlayer dielectric layer 24, the conformal dielectric layer 23, the upper hard mask 20a, and the lower hard mask 19a to expose a corresponding one of the memory structures 22 (i.e., to expose the cap 18a of the corresponding one of the memory structures 22) in the memory structure region 111a while each of the second via openings 25b penetrates the interlayer dielectric layer 24, the conformal dielectric layer 23, and the first hard mask layer 12 to expose a corresponding one of the metal lines 112 in the logic structure region 111b. In addition, as described above, the upper hard mask 20a includes a hard mask material different from that of the lower hard mask 19a, and thus has an etching rate different from that of the lower hard mask 19a with respect to the etchant for etching the interlayer dielectric layer 24, the conformal dielectric layer 23, and the upper hard mask 20a.

Referring to FIG. 1 and the example illustrated in FIG. 11, the method 100 proceeds to step S08, where a plurality of first contact vias 26a and a plurality of second contact vias 26b are formed. A contact material for forming the first contact vias 26a and the second contact vias 26b is deposited on the interlayer dielectric layer 24 to fill the first via openings 25a and the second via openings 25b. In some embodiments, the deposition of the contact material may be performed by a suitable deposition process, for example, but not limited to, CVD, PVD, ALD, electroless plating, electroplating, or other suitable deposition processes. The contact material may include, for example, but not limited to, copper, aluminum, tungsten, or combinations thereof. Other suitable materials for the contact vias 27a, 27b are within the contemplated scope of the present disclosure. An excess portion of the contact material on the interlayer dielectric layer 24 is removed, so as to form the first contact vias 26a and the second contact vias 26b. Removal of the excess portion of the contact material may be performed by a suitable planarization process (for example, but not limited to, the CMP process or other suitable planarization processes). Each of the first contact vias 26a penetrates the interlayer dielectric layer 24, the conformal dielectric layer 23, the upper hard mask 20a, and the lower hard mask 19a, and is connected to a corresponding one of the memory structures 22 (i.e., the cap 18a of the corresponding one of the memory structures 22) in the memory structure region 111a. Each of the second contact vias 26b penetrates the interlayer dielectric layer 24, the conformal dielectric layer 23, and the first mask layer 12, and is connected to a corresponding one of the metal lines 112 of the interconnect layer 11 in the logic structure region 111b.

In a method for manufacturing a semiconductor device of the present disclosure, a first hard mask layer is formed on a semiconductor substrate, and a second hard mask layer and a third hard mask layer are then used in formation of a memory structure (for example, but not limited to, an RRAM structure). The third hard mask layer is disposed on the second hard mask layer opposite to the first hard mask layer. A hard mask material for making the third hard mask layer is different from that for making the second hard mask layer, a hard mask material for making the second hard mask layer is the same as that for making the first hard mask layer, and the second hard mask layer has a thickness equal to that of the first hard mask layer. After formation of the memory structure, a bi-layered hard mask structure is formed on the memory structure, and includes a lower hard mask formed on the memory structure and an upper hard mask that is formed on the lower hard mask opposite to the memory structure. The upper hard mask is formed from the third hard mask layer. The lower hard mask is formed from the second hard mask layer, and thus has a thickness equal to that of the first hard mask layer and includes a hard mask material the same as that of the first hard mask layer. In the formation of a via opening to expose the memory structure in a memory structure region and another via opening to expose a metal line in a logic structure region, a portion of the upper hard mask and a portion of the lower hard mask to be removed for the formation of the via opening to expose the memory structure can be removed completely when a portion of the first hard mask layer to be removed for the formation of the another via opening to expose the metal line in the logic structure region is removed completely. Therefore, a contact via thus formed to be connected to the memory structure will not be isolated from the memory structure due to the presence of residues of a hard mask material. The performance and the yield of the semiconductor device including the memory structure can be enhanced accordingly.

In accordance with some embodiments of the present disclosure, a method for manufacturing a semiconductor device includes: forming a hard mask layer on a semiconductor substrate, the hard mask layer including a first hard mask material; forming a memory structure on the hard mask layer; forming a lower hard mask on the memory structure, the lower hard mask including a second hard mask material which has an etching rate the same as an etching rate of the first hard mask material with respect to a first etchant; forming an upper hard mask on the lower hard mask opposite to the memory structure, the upper hard mask including a third hard mask material which has an etching rate different from an etching rate of the second hard mask material with a second etchant, which is different from the first etchant; forming an interlayer dielectric layer on the hard mask layer to cover the memory structure, the lower hard mask, and the upper hard mask; forming a first via opening and a second via opening using the first etchant and the second, the first via opening penetrating the interlayer dielectric layer, the upper hard mask, and the lower hard mask to expose the memory structure, the second via opening penetrating the interlayer dielectric layer and the hard mask layer; and forming a first contact via and a second contact via in the first via opening and the second via opening, respectively, the first contact via being connected to the memory structure.

In accordance with some embodiments of the present disclosure, the lower hard mask has a thickness which is equal to a thickness of the hard mask layer.

In accordance with some embodiments of the present disclosure, the third hard mask material has a dielectric constant value which is different from a dielectric constant value of the second hard mask material.

In accordance with some embodiments of the present disclosure, the second hard mask material is the same as the first hard mask material.

In accordance with some embodiments of the present disclosure, each of the first hard mask material and the second hard mask material includes silicon nitride, silicon oxide, silicon carbide, silicon oxynitride, silicon oxycarbide, silicon carbon nitride, or combinations thereof.

In accordance with some embodiments of the present disclosure, the third hard mask material is different from the second hard mask material.

In accordance with some embodiments of the present disclosure, the method for manufacturing a semiconductor device further includes, before formation of the interlayer dielectric layer, forming a conformal dielectric layer to cover the memory structure, the lower hard mask, and the upper hard mask, so that the first via opening and the second via opening further penetrating the conformal dielectric layer.

In accordance with some embodiments of the present disclosure, the conformal dielectric layer includes a dielectric material which is the same as the third hard mask material.

In accordance with some embodiments of the present disclosure, each of the dielectric material and the third hard mask material includes silicon nitride, silicon oxide, tetraethyl orthosilicate, silicon carbide, silicon oxynitride, silicon oxycarbide, silicon carbon nitride, or combinations thereof.

In accordance with some embodiments of the present disclosure, a method for manufacturing a semiconductor device includes: forming a first hard mask layer on a semiconductor substrate, the first hard mask layer including a first hard mask material; sequentially forming a barrier material layer, a bottom electrode material layer, a high-k dielectric material layer, a top electrode material layer, a capping material layer, a second hard mask layer, and a third hard mask layer on the first hard mask layer, the second hard mask layer including a second hard mask material which is the same as the first hard mask material, the third hard mask layer including a third hard mask material which is different from the second hard mask material; patterning the third hard mask layer, the second hard mask layer, the capping material layer, the top electrode material layer, the high-k dielectric material layer, the bottom electrode material layer, and the barrier material layer to form a memory structure on the first hard mask layer, a lower hard mask on the memory structure, and an upper hard mask on the lower hard mask opposite to the memory structure, the lower hard mask including the second hard mask material, the upper hard mask including the third hard mask material; forming an interlayer dielectric layer on the first hard mask layer to cover the memory structure, the lower hard mask, and the upper hard mask; forming a first via opening and a second via opening, the first via opening penetrating the interlayer dielectric layer, the upper hard mask, and the lower hard mask to expose the memory structure, the second via opening penetrating the interlayer dielectric layer and the first hard mask layer; and forming a first contact via and a second contact via in the first via opening and the second via opening, respectively, the first contact via being connected to the memory structure.

In accordance with some embodiments of the present disclosure, the second hard mask layer has a thickness which is equal to a thickness of the first hard mask layer.

In accordance with some embodiments of the present disclosure, the third hard mask layer has a thickness which is greater than a thickness of the second hard mask layer.

In accordance with some embodiments of the present disclosure, patterning of the third hard mask layer, the second hard mask layer, the capping material layer, the top electrode material layer, the high-k dielectric material layer, the bottom electrode material layer, and the barrier material layer includes: forming a patterned photoresist layer on the third hard mask layer; performing an etching process through the patterned photoresist layer to pattern the third hard mask layer while removing the patterned photoresist layer, so as to permit the third hard mask layer to include a bottom portion and a plurality of upper portions protruding in an upward direction away from the semiconductor substrate; and continuously performing the etching process through a patterned hard mask formed by the upper portions of the third hard mask layer until the first hard mask layer is exposed.

In accordance with some embodiments of the present disclosure, a semiconductor device includes a hard mask layer disposed on a semiconductor substrate, and including a first hard mask material; a memory structure disposed on the hard mask layer; a lower hard mask disposed on the memory structure, and including a second hard mask material which is the same as the first hard mask material; an upper hard mask disposed on the lower hard mask opposite to the memory structure, and including a third hard mask material which is different from the second hard mask material; an interlayer dielectric layer disposed over the hard mask layer, and covering the memory structure, the lower hard mask, and the upper hard mask; and a first contact via penetrating the interlayer dielectric layer, the upper hard mask, and the lower hard mask, and being connected to the memory structure.

In accordance with some embodiments of the present disclosure, the lower hard mask has a thickness which is equal to a thickness of the hard mask layer.

In accordance with some embodiments of the present disclosure, the semiconductor device further includes: a second contact via penetrating the interlayer dielectric layer and the hard mask layer; and an interconnect layer disposed below the hard mask layer, and including a first conductive interconnect connected to the memory structure and a second conductive interconnect connected to the second contact via.

In accordance with some embodiments of the present disclosure, the semiconductor device further includes: a conformal dielectric layer disposed below the interlayer dielectric layer. The conformal dielectric layer conformally covers the memory structure, the lower hard mask, the upper hard mask, and the hard mask layer, and is penetrated by the first contact via and the second contact via.

In accordance with some embodiments of the present disclosure, each of the first hard mask material and the second hard mask material includes silicon nitride, silicon oxide, silicon carbide, silicon oxynitride, silicon oxycarbide, silicon carbon nitride, or combinations thereof.

In accordance with some embodiments of the present disclosure, the conformal dielectric layer includes a dielectric material which is the same as the third hard mask material.

In accordance with some embodiments of the present disclosure, each of the dielectric material and the third hard mask material includes silicon nitride, silicon oxide, tetraethyl orthosilicate, silicon carbide, silicon oxynitride, silicon oxycarbide, silicon carbon nitride, or combinations thereof.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a hard mask layer on a semiconductor substrate, the hard mask layer including a first hard mask material;
forming a memory structure on the hard mask layer;
forming a lower hard mask on the memory structure, the lower hard mask including a second hard mask material which has an etching rate the same as an etching rating of the first hard mask material with respect to a first etchant;
forming an upper hard mask on the lower hard mask opposite to the memory structure, the upper hard mask including a third hard mask material which has an etching rate different from an etching rate of the second hard mask material with a second etchant different from the first etchant;
forming an interlayer dielectric layer on the hard mask layer to cover the memory structure, the lower hard mask, and the upper hard mask;
forming a first via opening and a second via opening using the first etchant and the second etchant, the first via opening penetrating the interlayer dielectric layer, the upper hard mask, and the lower hard mask to expose the memory structure, the second via opening penetrating the interlayer dielectric layer and the hard mask layer; and
forming a first contact via and a second contact via in the first via opening and the second via opening, respectively, the first contact via being connected to the memory structure.

2. The method according to claim 1, wherein the lower hard mask has a thickness which is equal to a thickness of the hard mask layer.

3. The method according to claim 1, wherein the third hard mask material has a dielectric constant value which is different from a dielectric constant value of the second hard mask material.

4. The method according to claim 1, wherein the second hard mask material is the same as the first hard mask material.

5. The method according to claim 4, wherein each of the first hard mask material and the second hard mask material includes silicon nitride, silicon oxide, silicon carbide, silicon oxynitride, silicon oxycarbide, silicon carbon nitride, or combinations thereof.

6. The method according to claim 1, wherein the third hard mask material is different from the second hard mask material.

7. The method according to claim 6, further comprising, before formation of the interlayer dielectric layer, forming a conformal dielectric layer to cover the memory structure, the lower hard mask, and the upper hard mask, so that the first via opening and the second via opening further penetrating the conformal dielectric layer.

8. The method according to claim 7, wherein the conformal dielectric layer includes a dielectric material which is the same as the third hard mask material.

9. The method according to claim 8, wherein each of the dielectric material and the third hard mask material includes silicon nitride, silicon oxide, tetraethyl orthosilicate, silicon carbide, silicon oxynitride, silicon oxycarbide, silicon carbon nitride, or combinations thereof.

10. A method for manufacturing a semiconductor device, comprising:
forming a first hard mask layer on a semiconductor substrate, the first hard mask layer including a first hard mask material;
sequentially forming a barrier material layer, a bottom electrode material layer, a high-k dielectric material layer, a top electrode material layer, a capping material layer, a second hard mask layer, and a third hard mask layer on the first hard mask layer, the second hard mask layer including a second hard mask material which is the same as the first hard mask material, the third hard mask layer including a third hard mask material which is different from the second hard mask material;
patterning the third hard mask layer, the second hard mask layer, the capping material layer, the top electrode material layer, the high-k dielectric material layer, the bottom electrode material layer, and the barrier material layer to form a memory structure on the first hard mask layer, a lower hard mask on the memory structure, and an upper hard mask on the lower hard mask opposite to the memory structure, the lower hard mask including the second hard mask material, the upper hard mask including the third hard mask material;
forming an interlayer dielectric layer on the first hard mask layer to cover the memory structure, the lower hard mask, and the upper hard mask;
forming a first via opening and a second via opening, the first via opening penetrating the interlayer dielectric layer, the upper hard mask, and the lower hard mask to expose the memory structure, the second via opening penetrating the interlayer dielectric layer and the first hard mask layer; and
forming a first contact via and a second contact via in the first via opening and the second via opening, respectively, the first contact via being connected to the memory structure.

11. The method according to claim 10, wherein the second hard mask layer has a thickness which is equal to a thickness of the first hard mask layer.

12. The method according to claim 10, wherein the third hard mask layer has a thickness which is greater than a thickness of the second hard mask layer.

13. The method according to claim 10, wherein patterning of the third hard mask layer, the second hard mask layer, the capping material layer, the top electrode material layer, the high-k dielectric material layer, the bottom electrode material layer, and the barrier material layer includes:
forming a patterned photoresist layer on the third hard mask layer;
performing an etching process through the patterned photoresist layer to pattern the third hard mask layer while removing the patterned photoresist layer, so as to permit the third hard mask layer to include a bottom portion and a plurality of upper portions protruding in an upward direction away from the semiconductor substrate; and
continuously performing the etching process through a patterned hard mask formed by the upper portions of the third hard mask layer until the first hard mask layer is exposed.

14. A semiconductor device, comprising:
a hard mask layer disposed on a semiconductor substrate, and including a first hard mask material;
a memory structure disposed on the hard mask layer;
a lower hard mask disposed on the memory structure, and including a second hard mask material which is the same as the first hard mask material;
an upper hard mask disposed on the lower hard mask opposite to the memory structure, and including a third hard mask material which is different from the second hard mask material;
an interlayer dielectric layer disposed over the hard mask layer, and covering the memory structure, the lower hard mask, and the upper hard mask; and
a first contact via penetrating the interlayer dielectric layer, the upper hard mask, and the lower hard mask, and being connected to the memory structure.

15. The semiconductor device according to claim 14, wherein the lower hard mask has a thickness which is equal to a thickness of the hard mask layer.

16. The semiconductor device according to claim 14, further comprising:
a second contact via penetrating the interlayer dielectric layer and the hard mask layer; and
an interconnect layer disposed below the hard mask layer, and including a first conductive interconnect connected to the memory structure and a second conductive interconnect connected to the second contact via.

17. The semiconductor device according to claim 16, further comprising a conformal dielectric layer disposed below the interlayer dielectric layer, the conformal dielectric layer conformally covering the memory structure, the lower hard mask, the upper hard mask, and the hard mask layer, and being penetrated by the first contact via and the second contact via.

18. The semiconductor device according to claim 14, wherein each of the first hard mask material and the second hard mask material includes silicon nitride, silicon oxide, silicon carbide, silicon oxynitride, silicon oxycarbide, silicon carbon nitride, or combinations thereof.

19. The semiconductor device according to claim 17, wherein the conformal dielectric layer includes a dielectric material which is the same as the third hard mask material.

20. The method according to claim 19, wherein each of the dielectric material and the third hard mask material includes silicon nitride, silicon oxide, tetraethyl orthosilicate, silicon carbide, silicon oxynitride, silicon oxycarbide, silicon carbon nitride, or combinations thereof.
